(19) United States
(12) Patent Application Publication
(10) Pub. No.: US 2023/0005878 A1
(43) Pub. Date: Jan. 5, 2023

(54) Temporary Chip Assembly, Display Panel, and Manufacturing Methods of Temporary Chip Assembly and Display Panel

(71) Applicant: CHONGQING KONKA PHOTOELECTRIC TECHNOLOGY RESEARCH INSTITUTE CO., LTD., Chongqing (CN)

(72) Inventors: Feng ZHAI, Chongqing (CN); Xia DENG, Chongqing (CN); CHUN-LUNG HSIAO, Chongqing (CN)

(21) Appl. No.: 17/941,035

(22) Filed: Sep. 9, 2022

Related U.S. Application Data
(63) Continuation of application No. PCT/CN2021/093434, filed on May 12, 2021.

(51) Int. Cl. H01L 23/00; H01L 25/075; H01L 33/00; H01L 33/62; H01L 25/16

(52) U.S. Cl. CPC H01L 24/81; H01L 25/0753; H01L 33/0093; H01L 33/62; H01L 25/167; H01L 24/95; H01L 24/05; H01L 24/13; H01L 24/16; H01L 2933/0066; H01L 2224/81409; H01L 2224/05609; H01L 2224/818; H01L 2224/13171; H01L 2224/13111; H01L 2224/13155; H01L 2224/13124; H01L 2224/13166; H01L 2224/13144; H01L 2224/13169; H01L 2224/13184; H01L 2224/13116; H01L 2224/13173; H01L 2224/13147; H01L 2224/13139; H01L 2224/81005; H01L 2224/95001; H01L 2224/16148; H01L 2224/16238; H01L 2224/8192; H01L 2224/81007

(57) ABSTRACT

A temporary chip assembly, a display panel, and manufacturing methods of the temporary chip assembly and the display panel are provided. In the display panel, welding points between a micro light-emitting chip and corresponding bonding pads on a display backboard are covered with pyrolytic adhesive to block water and oxygen, thereby slowing down or avoiding the oxidation of the welding points.

### CROSS REFERENCE

This application is a continuation of the PCT International Application No. PCT/CN2021/093434 filed on May 12, 2021, the entirety of which is herein incorporated by reference.

### TECHNICAL FIELD

The present disclosure relates to the field of display, in particular to a temporary chip assembly, a display panel, and manufacturing methods of the temporary chip assembly and the display panel.

### BACKGROUND

A Micro-LED is a new generation of display technology. Compared with liquid crystal display, the Micro-LED has higher photoelectric efficiency, higher brightness, higher contrast, and lower power consumption, and may also be combined with a flexible panel to achieve flexible display. The Micro-LED has the same luminous principle as a large-size or ordinary LED display in a related art. The LED display in the related art is usually achieved by printing solder paste, and then welding an LED chip and a PCB substrate through a Surface Mounted Technology (SMT), which is no longer suitable for the micro-LED.

At present, the welding between the micro-LED chip and a backboard is usually achieved by using metal with strong metal activeness such as indium In, and after bonding pads are made on the backboard, micro-LED chip and the backboard are bonded through massive welding technology so as to form a display panel. In the later use, when the display panel is in a certain water and oxygen condition, due to the strong metal activity of the bonding pads, welding points between the micro-LED chip and the bonding pads are easy to oxidize, and after oxidation, the resistance increases, the power consumption of the micro-LED chip increases, and the heat production increases until the micro-LED chip fails, so that the reliability of the micro-LED chip gets worse.

Therefore, how to slow down or avoid the oxidation phenomenon of the welding points is an urgent problem to be solved.

### SUMMARY

In view of the defects of the above related art, embodiments of the present disclosure provide a temporary chip assembly, a display panel and manufacturing methods of the temporary chip assembly and the display panel, which can solve the problem that welding points are easy to oxidize in related art.

The embodiments of the present disclosure provide a temporary chip assembly, which includes: a temporary substrate, a pyrolytic adhesive layer, and a plurality of micro light-emitting chips.

The pyrolytic adhesive layer formed by pyrolytic adhesive is arranged on a front surface of the temporary substrate.

The plurality of micro light-emitting chips are arranged on the pyrolytic adhesive layer.

The pyrolytic adhesive layer includes a plurality of mutually separated pyrolytic adhesive units which are in one-to-one correspondence with the plurality of micro light-emitting chip. Electrodes of each of the plurality of micro light-emitting chips are respectively embedded into the corresponding pyrolytic adhesive unit, and after the pyrolytic adhesive unit is heated, pyrolytic adhesive located between the electrodes of the micro light-emitting chip adheres to the micro light-emitting chip and is separated from the temporary substrate along with the micro light-emitting chip. A de-bonding temperature value of the pyrolytic adhesive is greater than or equal to a melting point value of bonding pads bonded with the electrodes.

In the above temporary chip assembly, the plurality of mutually separated pyrolytic adhesive units are formed on the temporary substrate, and the electrodes of each of the plurality of micro light-emitting chips are respectively embedded into the corresponding pyrolytic adhesive unit to be fixed on the temporary substrate. When each micro light-emitting chip is transferred from the temporary substrate subsequently, the pyrolytic adhesive unit may be heated under temperature control, and the pyrolytic adhesive between the electrodes of the micro light-emitting chip adheres to the micro light-emitting chip and is separated from the temporary substrate along with the micro light-emitting chip, so that the pyrolytic adhesive remains between the electrodes of the micro light-emitting chip transferred from the temporary substrate. After the electrodes of the micro light-emitting chip are welded to the bonding pads in the corresponding chip bonding area, the pyrolytic adhesive between the electrodes becomes liquid after being heated, and flows to the bonding pads along the electrodes, so as to cover the welding points between the electrodes and the bonding pads to block water and oxygen, thereby slowing down or avoiding the oxidation of the welding points, avoiding the increase in power consumption or even failure of the micro light-emitting chip due to oxidation, and improving the reliability of the micro light-emitting chip.

Based on the same inventive concept, the embodiments of the present disclosure also provide a display panel, which includes a display backboard and the plurality of micro light-emitting chips transferred from the above temporary chip assembly to the display backboard.

A driving circuit is arranged on a front surface of the display backboard. The driving circuit includes a plurality of chip bonding areas corresponding to a plurality of micro light-emitting chips, and each chip bonding area is provided with bonding pads corresponding to the electrodes of the micro light-emitting chip.

After each micro light-emitting chip is transferred from the temporary substrate to the corresponding chip bonding area, the electrodes of the micro light-emitting chip are welded to the corresponding bonding pads in the chip bonding area, the pyrolytic adhesive between the electrodes of the micro light-emitting chip becomes liquid after being heated, and flows to the bonding pads along the electrodes, so as to cover the welding points between the electrodes and the bonding pads.

In the above display panel, the welding points between the micro light-emitting chip and the corresponding bonding pads on the display backboard are covered with the pyrolytic adhesive to block water and oxygen, thereby slowing down or avoiding the oxidation of the welding points, improving the reliability of the micro light-emitting chip, and improving the yield and the reliability of the display panel.

Based on the same inventive concept, the embodiments of the present disclosure also provide a manufacturing method of a temporary chip assembly, which includes the following operations.

A temporary substrate is provided.

Pyrolytic adhesive is arranged on a front surface of the temporary substrate to form a pyrolytic adhesive layer, and a plurality of micro light-emitting chips are arranged on the pyrolytic adhesive layer.

The pyrolytic adhesive layer includes a plurality of mutually separated pyrolytic adhesive units which are in one-to-one correspondence with the plurality of micro light-emitting chip. Electrodes of each of the plurality of micro light-emitting chips are respectively embedded into the corresponding pyrolytic adhesive unit, and after the pyrolytic adhesive unit is heated, pyrolytic adhesive located between the electrodes of the micro light-emitting chip adheres to the micro light-emitting chip and is separated from the temporary substrate along with the micro light-emitting chip. A de-bonding temperature value of the pyrolytic adhesive is greater than or equal to a melting point value of bonding pads bonded with the electrodes.

In the above temporary chip assembly manufactured by the manufacturing method, the plurality of mutually separated pyrolytic adhesive units configured to bear the micro light-emitting chips are formed on the temporary substrate, and the electrodes of each of the plurality of micro light-emitting chips are respectively embedded into the corresponding pyrolytic adhesive unit. When each micro light-emitting chip is transferred from the temporary substrate subsequently, the pyrolytic adhesive unit may be heated under temperature control, and the pyrolytic adhesive between the electrodes of the micro light-emitting chip adheres to the micro light-emitting chip and is separated from the temporary substrate along with the micro light-emitting chip, so that the pyrolytic adhesive remains between the electrodes of the micro light-emitting chip. After the electrodes of the micro light-emitting chip are welded to the bonding pads in a corresponding chip bonding area, the pyrolytic adhesive between the electrodes becomes liquid after being heated, and flows to the bonding pads along the electrodes, so as to cover the welding points between the electrodes and the bonding pads to block water and oxygen, thereby slowing down or avoiding the oxidation of the welding points, and improving the reliability of the micro light-emitting chip.

Based on the same inventive concept, the embodiments of the present disclosure also provide a manufacturing method of the above display panel, which includes the following operations.

A display backboard and the above temporary chip assembly are manufactured. A driving circuit is arranged on a front surface of the display backboard, the driving circuit includes a plurality of chip bonding areas corresponding to the plurality of micro light-emitting chips, and each chip bonding area is provided with bonding pads corresponding to the electrodes of the micro light-emitting chip.

Each micro light-emitting chip is transferred from the temporary substrate to the corresponding chip bonding area to complete bonding. After the bonding is completed, the electrodes of the micro light-emitting chip are welded to the corresponding bonding pads in the chip bonding area, pyrolytic adhesive between the electrodes of the micro light-emitting chip becomes liquid after being heated, and flows to the bonding pads along the electrodes, so as to cover welding points between the electrodes and bonding pads.

In the process of manufacturing the display panel through the manufacturing method of the display panel, since the pyrolytic adhesive remains between the electrodes of the micro light-emitting chip, after the electrodes of the micro light-emitting chip are welded to the bonding pads in the corresponding chip bonding area, the pyrolytic adhesive between the electrodes becomes liquid after being heated, and flows to the bonding pads along the electrodes, so as to cover the welding points between the electrodes and the bonding pads to block water and oxygen, thereby slowing down or avoiding the oxidation of the welding points, improving the reliability of the micro light-emitting chip, and improving the yield and the reliability of the display panel.

### BRIEF DESCRIPTION OF THE DRAWINGS

FIG. 1(a) is a top view I of a temporary chip assembly provided in an embodiment of the present disclosure.

FIG. 1(b) is a section view in an A-A direction of FIG. 1(a).

FIG. 1(c) is a schematic diagram of picking up micro light-emitting chips on a transfer head provided in an embodiment of the present disclosure.

FIG. 1(d) is a microscopic schematic diagram of pyrolytic adhesive on a micro light-emitting chip provided in an embodiment of the present disclosure.

FIG. 2 is a top view II of a temporary chip assembly provided in an embodiment of the present disclosure.

FIG. 3(a) is a top view III of a temporary chip assembly provided in an embodiment of the present disclosure.

FIG. 3(b) is a section view in a C-C direction of FIG. 3(a).

FIG. 4(a) is a top view IV of a temporary chip assembly provided in an embodiment of the present disclosure;

FIG. 4(b) is a section view in a D-D direction of FIG. 4(a).

FIG. 5(a) is a flowchart of a manufacturing method of a temporary chip assembly provided in an embodiment of the present disclosure.

FIG. 5(b) is a schematic diagram of forming an integrated pyrolytic adhesive layer provided in an embodiment of the present disclosure.

FIG. 5(c) is a section view in an E-E direction of FIG. 5(b).

FIG. 5(d) is a schematic diagram of a growth substrate provided in an embodiment of the present disclosure.

FIG. 5(e) is a schematic diagram of attaching a growth substrate to a temporary substrate provided in an embodiment of the present disclosure.

FIG. 5(f) is a schematic diagram of stripping a growth substrate provided in an embodiment of the present disclosure.

FIG. 5(g) is a schematic diagram of transferring micro light-emitting chips to an integrated pyrolytic adhesive layer provided in an embodiment of the present disclosure.

FIG. 5(h) is a section view in an F-F direction of FIG. 5(g).

FIG. 6(a) is a flowchart of another manufacturing method of a temporary chip assembly provided in an embodiment of the present disclosure.

FIG. 6(b) is another schematic diagram of forming an integrated pyrolytic adhesive layer provided in an embodiment of the present disclosure.

FIG. 6(c) is a schematic diagram of a pyrolytic adhesive unit provided in an embodiment of the present disclosure.

FIG. 6(d) is a section view in a G-G direction of FIG. 6(c).

FIG. 6(e) is another schematic diagram of attaching a growth substrate to a temporary substrate provided in an embodiment of the present disclosure;

FIG. 6(f) is another schematic diagram of stripping a growth substrate provided in an embodiment of the present disclosure.

FIG. 7(a) is a schematic diagram of a display backboard provided in another exemplary embodiment of the present disclosure.

FIG. 7(b) is a schematic diagram of transferring micro light-emitting chips to a display backboard by a transfer head provided in another exemplary embodiment of the present disclosure.

FIG. 8 is a schematic diagram I of a pyrolytic adhesive coating provided in another exemplary embodiment of the present disclosure.

FIG. 9(a) is a schematic diagram II of a pyrolytic adhesive coating provided in another exemplary embodiment of the present disclosure.

FIG. 9(b) is a schematic diagram III of a pyrolytic adhesive coating provided in another exemplary embodiment of the present disclosure.

FIG. 10(a) is a schematic diagram of a manufacturing method of a display panel provided in another exemplary embodiment of the present disclosure.

FIG. 10(b) is a schematic diagram of attaching a transfer head to a temporary substrate provided in another exemplary embodiment of the present disclosure.

FIG. 10(c) is a schematic diagram of picking up a micro light-emitting chip by a transfer head provided in another exemplary embodiment of the present disclosure.

FIG. 10(d) is a schematic diagram of transferring micro light-emitting chips to a display backboard by a transfer head provided in another exemplary embodiment of the present disclosure.

FIG. 10(e) is a schematic diagram of a pyrolytic adhesive coating provided in another exemplary embodiment of the present disclosure.

FIG. 10(f) is a schematic diagram of stripping a transfer head provided in another exemplary embodiment of the present disclosure.

Reference signs are as follows:

10—integrated pyrolytic adhesive layer, 11—temporary substrate, 12—pyrolytic adhesive unit, 121—pyrolytic adhesive, 122—pyrolytic adhesive coating, 13—micro light-emitting chip, 131—electrode, 132—epitaxial layer bottom surface, 2—transfer head, 3—growth substrate, 4—display backboard, 41—bonding pad, 42—welding point.

### DETAILED DESCRIPTION OF THE EMBODIMENTS

In order to facilitate the understanding of the present disclosure, the present disclosure will be described more fully below with reference to the relevant drawings. The exemplary implementations of the present disclosure are shown in the drawings. However, the present disclosure may be implemented in various different forms and is not limited to the implementation modes described herein. On the contrary, the purpose of providing these implementation modes is to make the understanding of the present disclosure more thorough and comprehensive.

Unless otherwise defined, all technical and scientific terms used herein have the same meaning as commonly understood by those skilled in the art of the present disclosure. The terms used herein is only for the purpose of describing the specific implementation modes of the present disclosure and is not intended to limit the present disclosure.

In the related art, when a display panel is in a certain water and oxygen condition in the later use, due to the strong metal activity of bonding pads, welding points between a micro-LED chip and the bonding pads are easy to oxidize, after oxidation, the resistance increases, the power consumption of the micro-LED chip increases, and the heat production increases until the micro-LED chip fails, so that the reliability of the micro-LED chip gets worse.

Based on this, a solution is provided in the embodiments of the present disclosure to solve the above technical problems, the details of which will be elaborated in subsequent embodiments.

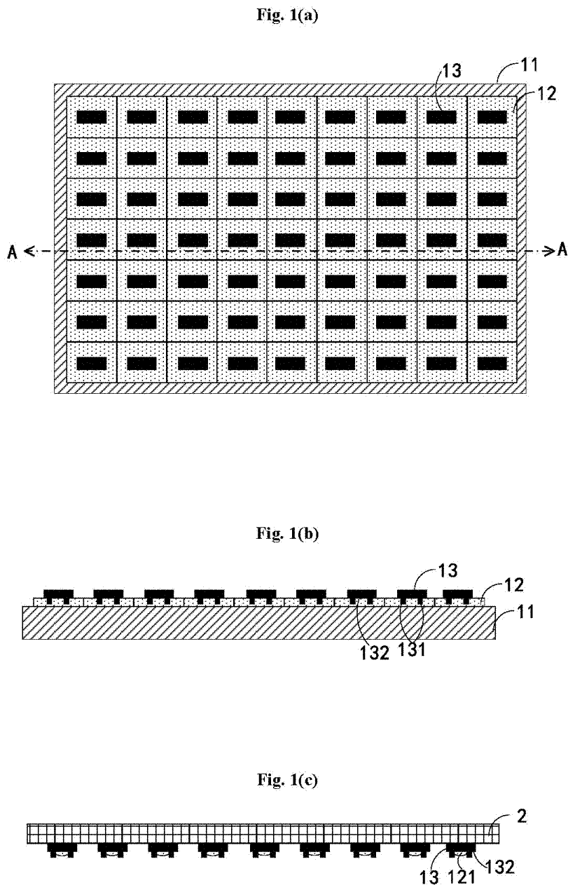

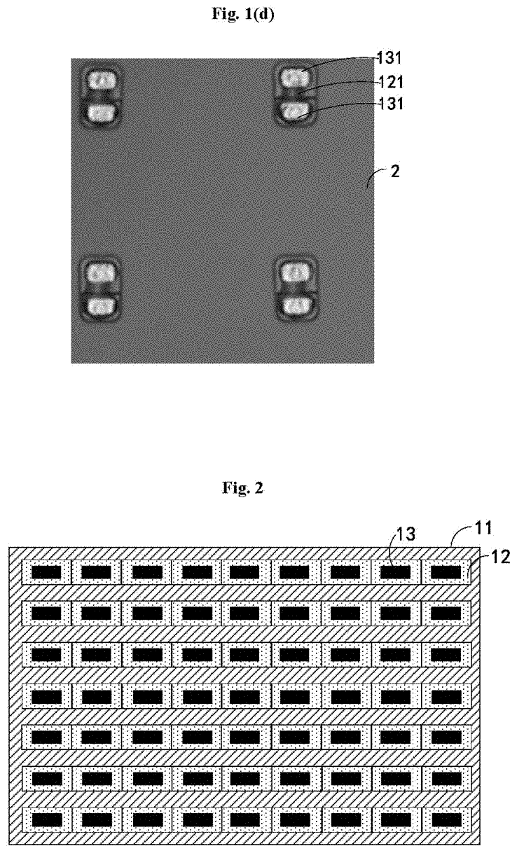

The embodiment provides a temporary chip assembly, as shown in FIG. 1(a) to FIG. 1(b), which includes, but not limited to, a temporary substrate 11.

The temporary substrate 11 in the embodiment may also be referred to as a transient substrate or a transfer substrate, and its material may be flexibly selected, for example, but not limited to, any one of glass, sapphire, quartz, and silicon.

A pyrolytic adhesive layer formed by pyrolytic adhesive is arranged on a front surface of the temporary substrate 11 (in the embodiment, the front surface of the temporary substrate 11 is one surface configured to bear a micro light-emitting chip). A de-bonding temperature value of the pyrolytic adhesive in the embodiment is greater than or equal to a melting point value of bonding pads bonded (also known as welded) with electrodes of the micro light-emitting chip. The de-bonding temperature value of the pyrolytic adhesive in the embodiment refers to a temperature critical value at which the pyrolytic adhesive is heated to change from a solid or semi-solid state to a liquid state. After the pyrolytic adhesive changes from the solid or semi-solid state to the liquid state, the fixation effect on the micro light-emitting chip bonded thereto (which may also be understood as the bonding strength) is reduced or even reduced to the minimum. It should be understood that the material of the pyrolytic adhesive in the embodiment may be flexibly selected under the above conditions, which is not limited.

As shown in FIG. 1(a) and FIG. 1(b), the pyrolytic adhesive layer includes a plurality of mutually separated pyrolytic adhesive units 12. The plurality of pyrolytic adhesive units 12 are mutually separated, that is, the adjacent pyrolytic adhesive units 12 are mutually separated, so that the pyrolytic adhesive units 12 are independent of each other.

The temporary chip assembly also includes a plurality of micro light-emitting chips 13 located on the pyrolytic adhesive layer 13. It should be understood that the micro light-emitting chip 13 in the embodiment may include, but not limited to, at least one of a Micro-LED chip or Mini-LED chip. Of course, the micro light-emitting chip 13 may also be replaced by other chips, which will not be repeated here.

The micro light-emitting chip 13 in the embodiment includes, but not limited to, an epitaxial layer and electrodes 131. The embodiment does not limit the specific structure of the epitaxial layer of the micro light-emitting chip. In an example, the epitaxial layer of the micro light-emitting chip 13 may include an N-type semiconductor, a P-type semiconductor, and an active layer located between the N-type semiconductor and the P-type semiconductor. The active layer may include a quantum well layer, and may also include other structures. In other examples, optionally, the epitaxial layer may further include at least one of a reflective layer and a passivation layer. The material and the shape of the electrode 131 in the embodiment are also not limited. For example, in an example, the material of the electrode 131 may include, but not limited to, at least one of Cr, Ni, Al, Ti, Au, Pt, W, Pb, Rh, Sn, Cu and Ag.

In an example of the embodiment, the plurality of pyrolytic adhesive units 12 are in one-to-one correspondence with the plurality of micro light-emitting chips 13, and the electrodes 131 of each of the plurality of micro light-emitting chips 13 are respectively embedded into the corresponding pyrolytic adhesive unit 12. Of course, it should be understood that in some examples, the number of the pyrolytic adhesive units 12 may also be larger than the number of the micro light-emitting chips 13. In the example, a part of pyrolytic adhesive units 12 may not be provided with the micro light-emitting chips, the situation shown in the example belongs to a case of equivalent replacement, which will not be repeated here.

As shown in FIG. 1(b), the electrodes 131 of each micro light-emitting chip 13 are embedded into the corresponding pyrolytic adhesive unit 12, and there is a part of the pyrolytic adhesive between the electrodes 131. When the micro light-emitting chip 13 is transferred from the temporary substrate 11, the part of the pyrolytic adhesive becomes liquid or semi-liquid after being heated (for example, its temperature value is greater than or equal to its de-bonding temperature value), is pulled away from the temporary substrate 11 by the pulling force away from the front surface of the temporary substrate 11 (the pyrolytic adhesive units 12 are mutually separated to be more favorable for the part of the pyrolytic adhesive to be separated from the temporary substrate 11), and separated from the temporary substrate 11 along with the micro light-emitting chip 13, and remains between the electrodes 131 of the micro light-emitting chip 13. For example, an example is shown in FIG. 1(c) and FIG. 1(d), when the micro light-emitting chip 13 picked up from the temporary substrate 11 through a transfer head 2 is transferred, the pyrolytic adhesive remains between the electrodes 131 of the picked-up micro light-emitting chip 13. The shape of the part of the pyrolytic adhesive 121 is not limited here. It should be understood that the part of the pyrolytic adhesive 121 may be bonded to the electrodes 131, or may be bonded to an epitaxial layer bottom surface 132 (that is, a surface, on which the electrodes 131 are arranged, of the epitaxial layer of the micro light-emitting chip 13), or may be bonded to the electrodes 131 and the epitaxial layer bottom surface 132 simultaneously.

Of course, it should be understood that the size and the shape of the pyrolytic adhesive unit 12, and the structure of the micro light-emitting chip 13, which is embedded into the corresponding pyrolytic adhesive unit 12, in the embodiment may be set flexibly. In order to facilitate the understanding, the embodiment is described below with reference to several examples.

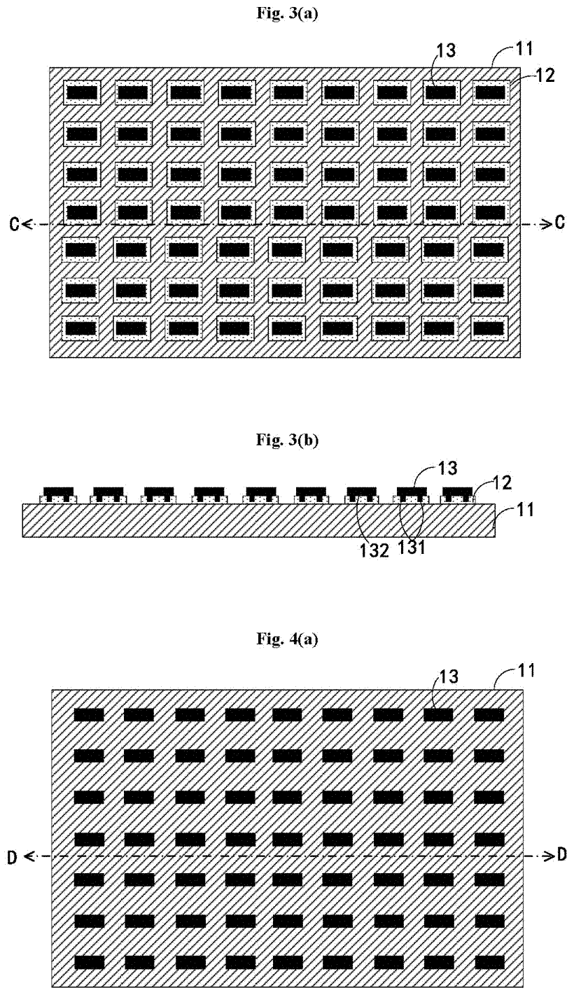

The difference between an example shown in FIG. 2 and the temporary chip assembly shown in FIG. 1(a) is that the row spacing of the pyrolytic adhesive unit 12 is larger. The shape of the orthographic projection of the pyrolytic adhesive unit 12 in FIG. 1(a) and FIG. 2 on the temporary substrate 11 is matched with the shape of the orthographic projection of the corresponding micro light-emitting chip 13 on the temporary substrate 11, and the area of the orthographic projection of the pyrolytic adhesive unit 12 on the temporary substrate 11 is greater than the area of the orthographic projection of the micro light-emitting chip 13 on the temporary substrate 11. The difference between an example shown in FIG. 3(a) and FIG. 3(b) and the temporary chip assembly shown in FIG. 2 is that the column spacing of the pyrolytic adhesive unit 12 is larger.

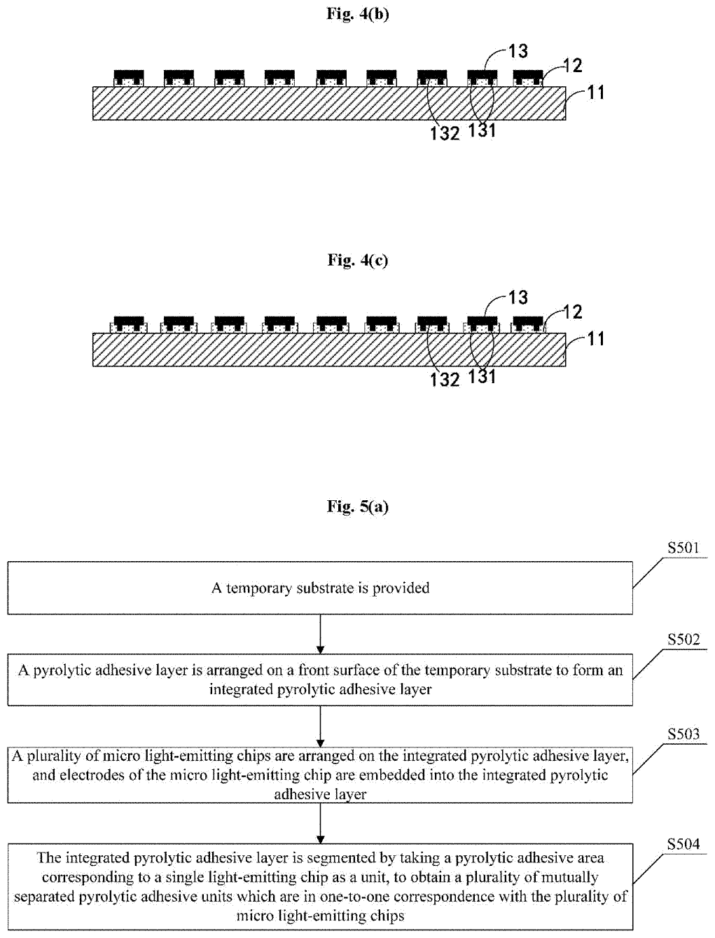

Another example is shown in FIG. 4(a) and FIG. 4(b). In the example, a shape and an area of an orthographic projection of the pyrolytic adhesive unit 12 on the temporary substrate 11 are matched with a shape and an area of an orthographic projection of the corresponding micro light-emitting chips 13 on the temporary substrate 11. In other words, the shape of the orthographic projection of the pyrolytic adhesive unit 12 on the temporary substrate 11 is the same or substantially the same as the shape of the orthographic projection of the corresponding micro light-emitting chip 13 on the temporary substrate 11. The area of the orthographic projection of the pyrolytic adhesive unit 12 on the temporary substrate 11 is the same or substantially the same as the area of the orthographic projection of the corresponding micro light-emitting chip 13 on the temporary substrate 11, that is, the area of the orthographic projection of the pyrolytic adhesive unit 12 on the temporary substrate 11 may be slightly smaller or slightly larger than the area of the orthographic projection of the corresponding micro light-emitting chip 13 on the temporary substrate 11. In the example, compared with the temporary chip assembly shown in FIG. 1(a) and FIG. 2, the pyrolytic adhesive unit 12 has a larger row spacing and column spacing, so that when the micro light-emitting chip 13 is transferred from the temporary substrate 11, the transfer is more convenient, and it may better ensure that the pyrolytic adhesive remains between the transferred micro light-emitting chips 13.

In an example of the embodiment, when the micro light-emitting chip 13 is embedded into the corresponding pyrolytic adhesive unit 12, it may only be that the electrodes 131 of the micro light-emitting chip 13 are embedded into the corresponding pyrolytic adhesive unit 12, and the epitaxial layer bottom surface 132 is not in contact with the pyrolytic adhesive unit 12. At this time, the part of the pyrolytic adhesive 121 between the electrodes 131 may be controlled to become liquid or semi-liquid after being heated, and may only be bonded with the electrodes 131 other than the epitaxial layer bottom surface 132. Of course, the distance between the epitaxial layer bottom surface 132 and the pyrolytic adhesive unit 12 may also be appropriately controlled, so that the part of the pyrolytic adhesive 121 between the electrodes 131 is heated and expanded to be in contact with the epitaxial layer bottom surface 132 to realize bonding, thereby increasing the bonding area between the part of the pyrolytic adhesive 121 and the epitaxial layer bottom surface 132 of the micro light-emitting chip 13, which is more favorable for the part of the pyrolytic adhesive 121 to be separated from the temporary substrate 11 and/or the pyrolytic adhesive of other parts of the pyrolytic adhesive unit 12 and remain between the electrodes 131.

In another example of the embodiment, the epitaxial layer bottom surface 132 of the micro light-emitting chip 13 is attached to the corresponding pyrolytic adhesive unit 12, for example, as shown in FIG. 3(b) and FIG. 4(b), so as to increase the direct bonding area between the pyrolytic adhesive unit 12 and the micro light-emitting chip 13, which is more favorable for the part of the pyrolytic adhesive 121 to be separated from the temporary substrate 11 and/or other parts of the pyrolytic adhesive unit 12 and remain between the electrodes 131.

In another example of the embodiment, the epitaxial layer bottom surface 132 of the micro light-emitting chip 13 is embedded into the corresponding pyrolytic glue unit 12, as shown in FIG. 4(c), so as to increase the direct bonding area between the pyrolytic adhesive unit 12 and the micro light-emitting chip 13, which is more favorable for the part of the pyrolytic adhesive 121 to be separated from the temporary substrate 11 and/or other parts of the pyrolytic adhesive unit 12 and remain between the electrodes 131.

In order to facilitate better understanding, the embodiment describes a manufacturing method of the temporary chip assembly in the above example by way of examples below.

A manufacturing method of a temporary chip assembly provided in the embodiment includes the following operations.

A temporary substrate is provided.

Pyrolytic adhesive arranged on a front surface of the temporary substrate forms a pyrolytic adhesive layer, and a plurality of micro light-emitting chips are arranged on the pyrolytic adhesive layer. Herein, the pyrolytic adhesive layer includes a plurality of mutually separated pyrolytic adhesive units which are in one-to-one correspondence with the plurality of micro light-emitting chip. Electrodes of each of the plurality of micro light-emitting chips are respectively embedded into the corresponding pyrolytic adhesive unit, and after the pyrolytic adhesive unit is heated, pyrolytic adhesive located between the electrodes of the micro light-emitting chip adheres to the micro light-emitting chip and is separated from the temporary substrate along with the micro light-emitting chip 13. It should be understood that, in the embodiment, the plurality of pyrolytic adhesive units may be formed after or before transferring the micro light-emitting chip to the temporary substrate. In order to facilitate the understanding, the following two cases are respectively described by examples.

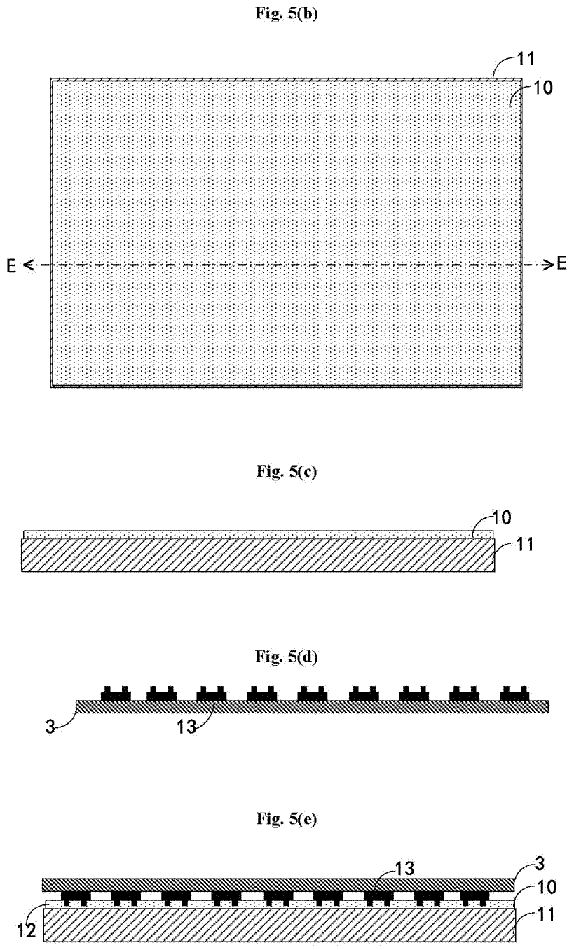

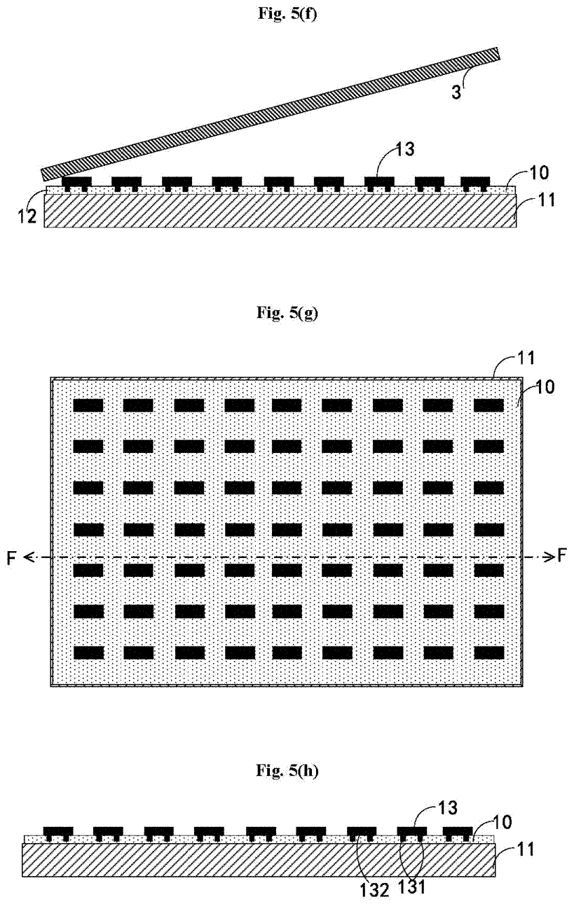

As shown in FIG. 5(a), the plurality of pyrolytic adhesive units are formed after transferring the micro light-emitting chip to the temporary substrate. The manufacturing method of the temporary chip assembly in the example includes the following operations.

At S501, the temporary substrate is provided.

At S502, a pyrolytic adhesive layer is arranged on a front surface of the temporary substrate to form an integrated pyrolytic adhesive layer.

For example, as shown in FIG. 5(b) and FIG. 5(c), the integrated pyrolytic adhesive layer 10 is formed on a front surface of the temporary substrate 11. The embodiment does not limit the process of forming the integrated pyrolytic adhesive layer 10 on the front surface of the temporary substrate 11, for example, but not limited to, molding, silk screen printing, spraying, coating, and the like. In one application scenario, the thickness of the integrated pyrolytic adhesive layer 10 may be greater than or equal to the height of the electrode of the micro light-emitting chip.

At S503, the plurality of micro light-emitting chips are arranged on the integrated pyrolytic adhesive layer, and the electrodes of the micro light-emitting chip are embedded into the integrated pyrolytic adhesive layer.

In the example, the plurality of micro light-emitting chips may be transferred from, but not limited to, a growth substrate or other substrates to the integrated pyrolytic adhesive layer, and the transfer manner may be flexibly adopted. In order to facilitate the understanding, the following will be described with reference to an application example.

In the present disclosure example, as shown in FIG. 5(d), the plurality of micro light-emitting chips 13 are formed on the growth substrate 3. In the present disclosure example, the manner of growing the micro light-emitting chip 13 on the growth substrate 3 is not limited. The material of the growth substrate 3 in the present disclosure example may be, but not limited to, sapphire, silicon carbide, silicon, and gallium arsenide, and may also be other semiconductor materials, which is not limited herein.

As shown in FIG. 5(e), one surface, on which the plurality of micro light-emitting chips 13 are formed, of the growth substrate 3 is attached to the surface, on which the integrated pyrolytic adhesive layer 10 is formed, of the temporary substrate 11. After lamination, the electrodes of each of the plurality of micro light-emitting chips 13 are embedded into the integrated pyrolytic adhesive layer 10, and optionally, the epitaxial layer bottom surfaces of the plurality of micro light-emitting chips 13 are attached to the integrated pyrolytic adhesive layer 10, or embedded into the integrated pyrolytic adhesive layer 10.

As shown in FIG. 5(f), the growth substrate 3 is stripped, for example, the growth substrate 3 may be stripped through, but not limited to, laser irradiation. After stripping, the micro light-emitting chip 13 adheres to the integrated pyrolytic adhesive layer 10, as shown in FIG. 5(g) and FIG. 5(h).

At S504, the integrated pyrolytic adhesive layer is segmented by taking a pyrolytic adhesive area corresponding to a single light-emitting chip as a unit, to obtain the plurality of mutually separated pyrolytic adhesive units which are in one-to-one correspondence with the plurality of micro light-emitting chips.

In the example, the integrated pyrolytic adhesive layer may be segmented through, but not limited to, cutting, etching (for example, but not limited to, reactive ion etching) and other processes. The segmented pyrolytic adhesive unit 12 is shown in, but not limited to, FIG. 1(a) to FIG. 4(c).

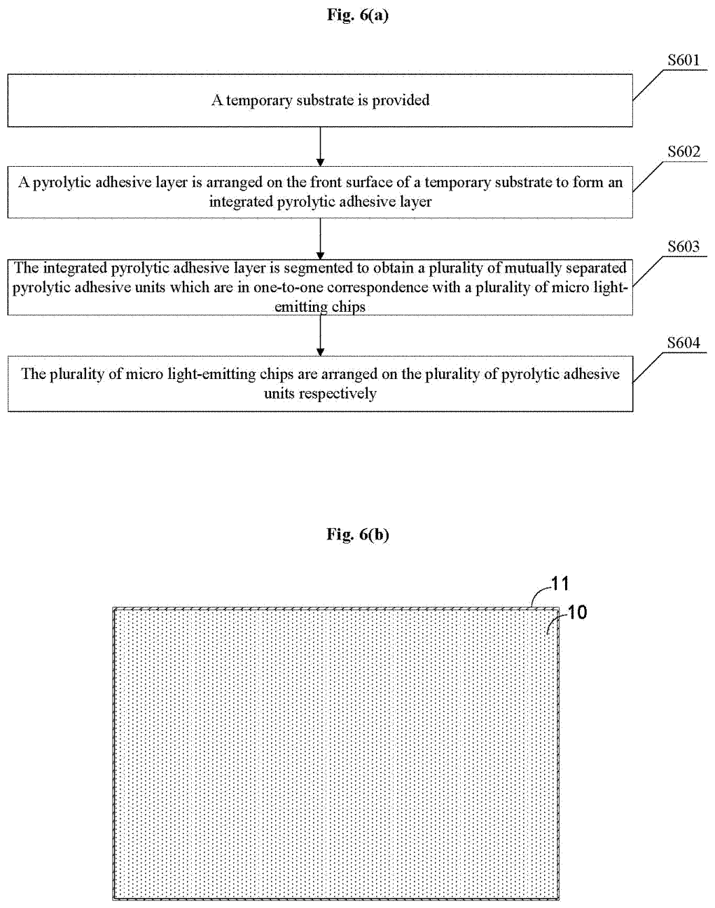

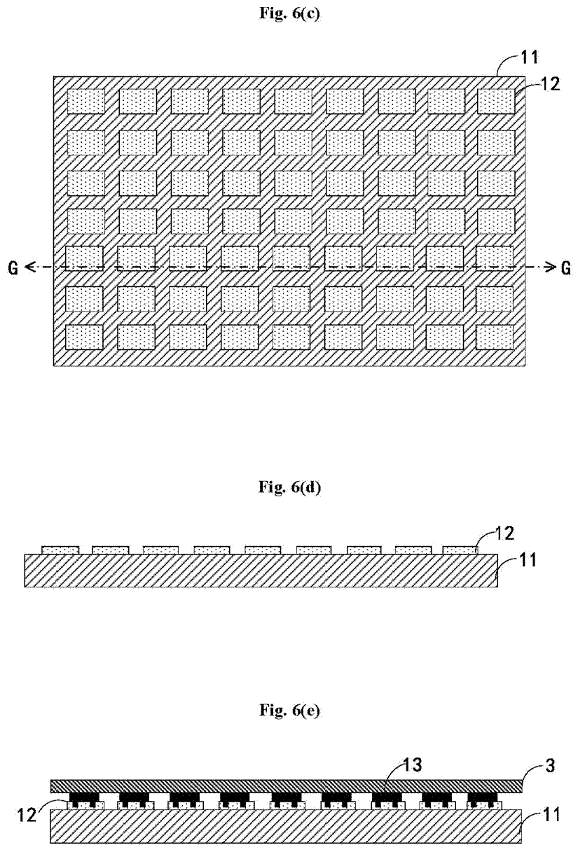

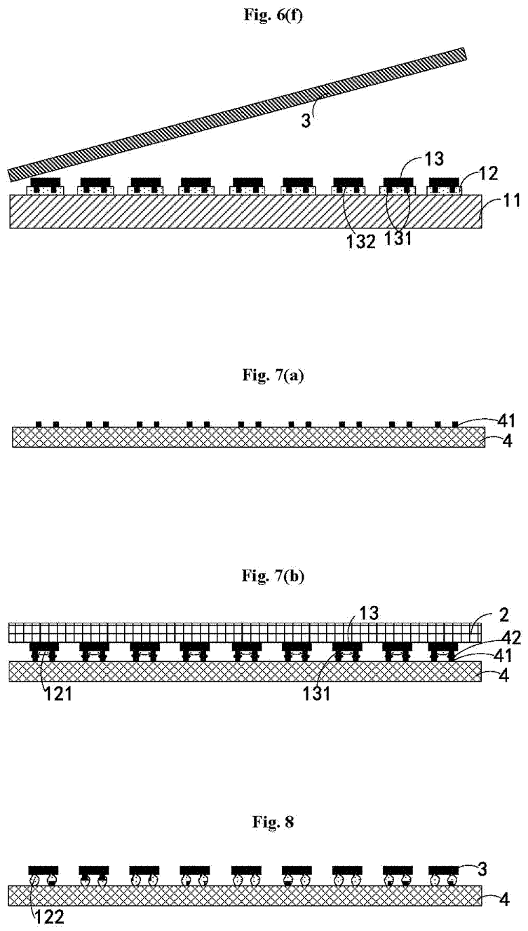

As shown in FIG. 6(a), the plurality of pyrolytic adhesive units are formed before transferring the micro light-emitting chip to the temporary substrate. The manufacturing method of the temporary chip assembly in the example includes the following operations.

At S601, the temporary substrate is provided.

At S602, the pyrolytic adhesive layer is arranged on a front surface of the temporary substrate to form the integrated pyrolytic adhesive layer. For example, as shown in FIG. 6(b), the integrated pyrolytic adhesive layer is formed on the temporary substrate 11.

At S603, the integrated pyrolytic adhesive layer is segmented to obtain the plurality of mutually separated pyrolytic adhesive units which are in one-to-one correspondence with the plurality of micro light-emitting chips.

In the example, the integrated pyrolytic adhesive layer may also be segmented through, but not limited to, cutting, etching and other processes. The segmented pyrolytic adhesive unit 12 is shown in, but not limited to, FIG. 6(c) to FIG. 6(d).

At S604, the plurality of micro light-emitting chips are arranged on the plurality of pyrolytic adhesive units respectively.

In the example, the plurality of micro light-emitting chips may be transferred from, but not limited to, the growth substrate or other substrates to the integrated pyrolytic adhesive layer, and the transfer manner may be flexibly adopted. In order to facilitate the understanding, the following will be described with reference to an application example.

As shown in FIG. 6(e), one surface, on which the plurality of micro light-emitting chips 13 are formed, of the growth substrate 3 is attached to the surface, on which the integrated pyrolytic adhesive layer 10 is formed, of the temporary substrate 11. After lamination, the electrodes of each of the plurality of micro light-emitting chips 13 are embedded into the pyrolytic adhesive unit 12, and optionally, the epitaxial layer bottom surface of each of the plurality of micro light-emitting chips 13 is attached to the corresponding pyrolytic adhesive unit 12, or embedded into the corresponding pyrolytic adhesive unit 12.

As shown in FIG. 6(f), the growth substrate 3 is stripped, for example, the growth substrate 3 may be stripped through, but not limited to, laser irradiation. After stripping, the micro light-emitting chip 13 adheres to the pyrolytic adhesive unit 12, as shown in FIG. 1(a) and FIG. 4(c).

It can be seen that, in the temporary assembly provided in the embodiment, the plurality of mutually separated pyrolytic adhesive units are formed on the temporary substrate, and the electrodes of each of the plurality of micro light-emitting chips are respectively embedded into the corresponding pyrolytic adhesive unit to be fixed on the temporary substrate. When each micro light-emitting chip is transferred from the temporary substrate subsequently, the pyrolytic adhesive unit may be heated under temperature control, and the pyrolytic adhesive between the electrodes of the micro light-emitting chip adheres to the micro light-emitting chip and is separated from the temporary substrate along with the micro light-emitting chip, so that the pyrolytic adhesive remains between the electrodes of the micro light-emitting chip transferred from the temporary substrate. After the electrodes of the micro light-emitting chip are welded to the bonding pads in the corresponding chip bonding area, the pyrolytic adhesive between the electrodes becomes liquid after being heated, and flows to the bonding pads along the electrodes, so as to cover the welding points between the electrodes and the bonding pads to block water and oxygen, thereby slowing down or avoiding the oxidation of the welding points, avoiding the increase in power consumption or even failure of the micro light-emitting chip due to oxidation, and improving the reliability of the micro light-emitting chip.

Another exemplary embodiment:

The embodiment provides a display panel, which includes a display backboard, and the plurality of micro light-emitting chips 13 transferred from the temporary chip assembly shown in the above embodiment to the display backboard.

As shown in FIG. 7(a), a driving circuit is arranged on a front surface of the display backboard 4. The driving circuit includes a plurality of chip bonding areas corresponding to the plurality of micro light-emitting chips 13. The chip bonding area is provided with bonding pads 41 corresponding to the electrodes of the micro light-emitting chip 13.

As shown in FIG. 7(b), after the micro light-emitting chip 13 is transferred from the temporary substrate 11 to the corresponding chip bonding area, the electrodes 131 of the micro light-emitting chip 13 are welded to the corresponding bonding pads 41 in the chip bonding area, and welding points 42 are formed at the welding positions between the electrodes 131 and the corresponding bonding pads 41. As shown in FIG. 8, pyrolytic adhesive 121 between the electrodes 131 of the micro light-emitting chip 13 becomes liquid after being heated, flows to the bonding pads 41 along the electrodes 131 (that is, using a rod climbing effect of the adhesive under the thermal effect), and covers each welding point 42 between the electrode 131 and the bonding pads 42 to form a pyrolytic adhesive coating 122 including the welding point 42. The pyrolytic adhesive coating 122 can block the water and oxygen of the welding point 42, slow down or avoid the oxidation of the welding point 42, avoid the increase in power consumption or even failure of the micro light-emitting chip 13 due to oxidation, and improve the reliability of the micro light-emitting chip 13.

The bonding pads 41 in the embodiment may be In pads, or pads made of other materials, or pads made of a composite material. For example, the end, close to the display backboard 4, of a bonding pad may not be In, and the end, away from the display backboard 4, may be In. Of course, it should be understood that the In material may also be replaced with other materials.

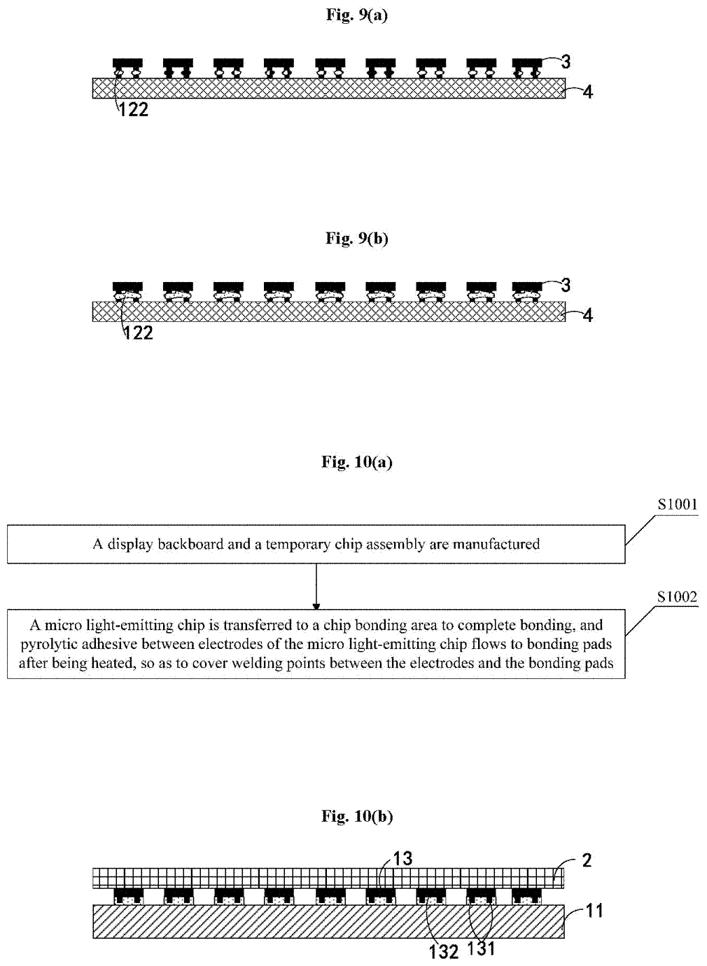

It should be understood that, in the embodiment, the pyrolytic adhesive coating 122 may only cover the welding point 42, for example, as shown in FIG. 9(a), and may also cover at least a part of the area, located above the welding point 42, of the electrode 131, and/or at least a part of the bonding pad under the welding point 42, for example, as shown in FIG. 8. In some examples, at least a part of the pyrolytic adhesive coating 122 may also be in contact with the epitaxial layer bottom surface of the micro light-emitting chip 13, as shown in FIG. 9(b).

According to the above examples, the specific shape of the pyrolytic adhesive coating 122 in the embodiment may be flexible and changeable, and is not limited to the shapes shown in the above examples, as long as the pyrolytic adhesive coating 122 can cover the welding point 42 to form water and oxygen isolation, which is not limited in the embodiment. It should be understood that the display backboard in the embodiment may be replaced with a lighting circuit board to manufacturing a lighting assembly.

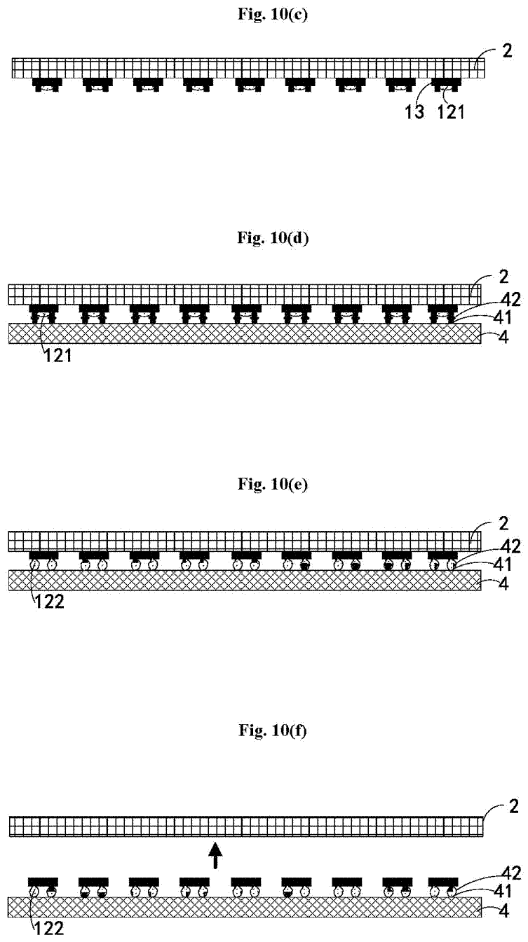

In order to facilitate the understanding, the embodiment also provides a manufacturing method of the display panel shown in the above examples, as shown in FIG. 10(a), which includes the following operations.

At S1001, a display backboard and the temporary chip assembly shown in the embodiment are manufactured.

The display backboard in the embodiment is shown in FIG. 7(a). The display backboard 4 may be an active or passive display backboard. A driving circuit is provided on a front surface of the display backboard 4. The driving circuit includes a plurality of chip bonding areas corresponding to the plurality of micro light-emitting chips 13. The chip bonding area is provided with bonding pads 41 corresponding to the electrodes of the micro light-emitting chip 13. The bonding pads 41 may be indium welding columns.

At S1002, each micro light-emitting chip is transferred from the temporary substrate to the corresponding chip bonding area to complete bonding. After the bonding is completed, the electrodes of the micro light-emitting chip are welded to the corresponding bonding pads in the chip bonding area, pyrolytic adhesive between the electrodes of the micro light-emitting chip becomes liquid after being heated, and flows to the bonding pads along the electrodes, so as to cover welding points between the electrodes and the bonding pads.

In order to facilitate the understanding, the following description takes the process of transferring the micro light-emitting core from the temporary substrate to the corresponding chip bonding area as an example. As shown in FIG. 10(b), a transfer head 2 is attached to the corresponding micro light-emitting chip 13 on the temporary substrate 11, and Pick&Place is performed by a Van der waals force mass transfer technology. In the process of picking up the micro light-emitting chip 13, the pyrolytic adhesive between the electrodes 131 of the micro light-emitting chip 13 is subjected to temperature control, so that the pyrolytic adhesive becomes soft (i.e., becomes liquid), and then the micro light-emitting chip 13 is transferred from the temporary substrate 11 through the transfer head 2. In the process of separating the micro light-emitting chip 13 from the temporary substrate 11, the pyrolytic adhesive between the electrodes of the micro light-emitting chip 13 becomes soft and is pulled away from the temporary substrate 11 under the action of the pulling force. Therefore, the part of the pyrolytic adhesive remains on the micro light-emitting chip 13, as shown in FIG. 10(c).

In an example of the embodiment, the de-bonding temperature value of the pyrolytic adhesive may be set to be equal to the melting point value of the bonding pads. When the micro light-emitting chip 13 is transferred from the temporary substrate 11 to the corresponding chip bonding area to complete bonding, that is, the electrodes of the micro light-emitting chip 13 are welded to the bonding pads 41, the pyrolytic adhesive 121 between the electrodes 131 of the micro light-emitting chip 13 is heated to become liquid, so that the adhesive flows to the bonding pads 41 along the electrodes, thereby covering the welding points between the electrodes 131 and the bonding pads 41. In the example, when the bonding pads 41 are heated to be melted, so as to be welded with the electrodes 131, the pyrolytic adhesive between the electrodes of the micro light-emitting chip 13 may be heated to become liquid. Of course, the bonding pads 41 may be preheated to be melted before transferring the micro light-emitting chip 13. After the chip is picked up from the temporary substrate 11 and transferred to the corresponding chip bonding area, the pyrolytic adhesive 121 between the electrodes of the micro light-emitting chip 13 is heated to become liquid in the process of welding the electrodes 131 to the bonding pads 41. In the way, in the process of welding the electrodes 131 to the bonding pads 41, the pyrolytic adhesive 121 flows to the bonding pads 41 along the electrodes 131, so as to cover the welding points 42 between the electrodes 131 and the bonding pads 41, for example, as shown in FIG. 10(e).

In another example of the embodiment, the de-bonding temperature value of the pyrolytic adhesive may be set to be greater than the melting point value of the bonding pads. In the example, after the electrodes 131 of the micro light-emitting chip 13 are welded to the corresponding pad 41 in the chip bonding area, the pyrolytic adhesive between the electrodes 131 of the micro light-emitting chip 13 may be heated (that is, the micro light-emitting chip is subjected to reflow treatment) to become liquid, and flows to the bonding pads 41 along the electrodes 131, so as to cover the welding points 42 between the electrodes 131 and the bonding pads 41. For example, an example is shown in FIG. 10(d), the electrodes 131 of the micro light-emitting chip 13 are welded to the corresponding bonding pads 41 in the chip bonding area to form the welding points 42. After the electrodes 131 of the micro light-emitting chip 13 are welded to the corresponding bonding pads 41 in the chip bonding area, the pyrolytic adhesive between the electrodes of the micro light-emitting chip 13 is heated to become liquid, so as to cover the welding points 42, for example, as shown in FIG. 10(e).

In an application scenario, timing is started after the electrodes 131 of the micro light-emitting chip 13 are welded to the corresponding bonding pads 41 in the chip bonding area. After a timing value reaches a preset time threshold, the pyrolytic adhesive between the electrodes 131 of the micro light-emitting chip 13 is heated to become liquid. In the embodiment, the value of the preset time threshold value may be set flexibly, for example, the value may be, but not limited to, greater than or equal to 10 seconds and less than or equal to 30 seconds.

In an example of the embodiment, the micro light-emitting chip 13 may be picked up from the temporary substrate 11 through, but not limited to, the transfer head 2 and transferred to the corresponding chip bonding area, and the pyrolytic adhesive 121 between the electrodes of the micro light-emitting chip 13 is heated through the transfer head 2, so that the temperature value of the pyrolytic adhesive 121 is greater than or equal to the de-bonding temperature value. Of course, in some examples, the pyrolytic adhesive 121 between the electrodes of the micro light-emitting chip 13 may not be heated through the transfer head 2, and the pyrolytic adhesive 121 may also be heated in other ways.

It can be seen that, in the display panel provided in the embodiment, the welding points between the micro light-emitting chip and the corresponding bonding pads on the display backboard are covered with pyrolytic adhesive to block water and oxygen, thereby slowing down or avoiding the oxidation of the welding points, improving the reliability of micro light-emitting chip, and improving the yield and the reliability of the display panel.

Yet another exemplary embodiment:

The embodiment also provides a display screen, which includes a frame and the display panel as shown above. The display panel is fixed on the frame. A photoelectric device of the display screen has better reliability, higher product reliability and yield, and may be applied to, but not limited to, various smart mobile terminals, vehicle terminals, PCs, monitors, electronic advertising boards, etc.

The embodiment also provides a spliced display screen, which may be formed by splicing at least two display screens as shown above.

It should be understood that the present disclosure of the disclosure is not limited to the above examples. For those of ordinary skill in the art, improvements or transformations may be made according to the above descriptions, and all these improvements and transformations should belong to the scope of protection of the appended claims of the disclosure.

What is claimed is:

1. A temporary chip assembly, comprising:
a temporary substrate;
a pyrolytic adhesive layer formed by pyrolytic adhesive, wherein the pyrolytic adhesive layer is arranged on a front surface of the temporary substrate; and
a plurality of micro light-emitting chips arranged on the pyrolytic adhesive layer;
wherein the pyrolytic adhesive layer comprises a plurality of mutually separated pyrolytic adhesive units which are in one-to-one correspondence with the plurality of micro light-emitting chips; electrodes of each of the plurality of micro light-emitting chips are respectively embedded into the corresponding pyrolytic adhesive unit, and after the pyrolytic adhesive unit is heated, pyrolytic adhesive located between the electrodes of the micro light-emitting chip adheres to the micro light-emitting chip and is separated from the temporary substrate along with the micro light-emitting chip; and a de-bonding temperature value of the pyrolytic adhesive is greater than or equal to a melting point value of bonding pads bonded with the electrodes.

2. The temporary chip assembly of claim 1, wherein a shape and an area of an orthographic projection of the pyrolytic adhesive unit on the temporary substrate are matched with a shape and an area of an orthographic projection of the corresponding micro light-emitting chip on the temporary substrate.

3. The temporary chip assembly of claim 1, wherein a surface, on which the electrodes are arranged, of an epitaxial layer of the micro light-emitting chip is attached to or embedded into the corresponding pyrolytic adhesive unit.

4. The temporary chip assembly of claim 1, wherein a shape of an orthographic projection of the pyrolytic adhesive unit on the temporary substrate is matched with a shape of an orthographic projection of the corresponding micro light-emitting chip on the temporary substrate, and an area of an orthographic projection of the pyrolytic adhesive unit on the temporary substrate is greater than an area of an orthographic projection of the corresponding micro light-emitting chip on the temporary substrate.

5. The temporary chip assembly of claim 1, wherein after the pyrolytic adhesive unit is heated, pyrolytic adhesive located on a surface, on which the electrodes are arranged, of an epitaxial layer of the micro light-emitting chip adheres to the micro light-emitting chip and is separated from the temporary substrate along with the micro light-emitting chip.

6. The temporary chip assembly of claim 1, wherein after the pyrolytic adhesive changes from a solid or semi-solid state to a liquid state, a bonding strength of the pyrolytic adhesive is reduced.

7. A display panel, comprising a display backboard and the plurality of micro light-emitting chips transferred from the temporary chip assembly of claim 1 to the display backboard;
wherein a driving circuit is arranged on a front surface of the display backboard, the driving circuit comprises a plurality of chip bonding areas corresponding to the plurality of micro light-emitting chips, and each chip bonding area is provided with bonding pads corresponding to the electrodes of the micro light-emitting chip; and
after each micro light-emitting chip is transferred from the temporary substrate to the corresponding chip bonding area, the electrodes of the micro light-emitting chip are welded to the corresponding bonding pads in the chip bonding area, the pyrolytic adhesive between the electrodes of the micro light-emitting chip becomes liquid after being heated, and flows to the bonding pads along the electrodes, so as to cover welding points between the electrodes and the bonding pads.

8. The display panel of claim 7, wherein the bonding pads are indium bonding pads.

9. A manufacturing method of the temporary chip assembly of claim 1, comprising:
providing a temporary substrate; and
arranging pyrolytic adhesive on a front surface of the temporary substrate to form a pyrolytic adhesive layer, and arranging a plurality of micro light-emitting chips on the pyrolytic adhesive layer;
wherein the pyrolytic adhesive layer comprises a plurality of mutually separated pyrolytic adhesive units which are in one-to-one correspondence with the plurality of micro light-emitting chips; electrodes of each of the plurality of micro light-emitting chips are respectively embedded into the corresponding pyrolytic adhesive unit, and after the pyrolytic adhesive unit is heated, the pyrolytic adhesive located between the electrodes of the micro light-emitting chip adheres to the micro light-emitting chip and is separated from the temporary substrate along with the micro light-emitting chip; and a de-bonding temperature value of the pyrolytic adhesive is greater than or equal to a melting point value of bonding pads bonded with the electrodes.

10. The manufacturing method of claim 9, wherein arranging pyrolytic adhesive on a front surface of the temporary substrate to form a pyrolytic adhesive layer, and arranging a plurality of micro light-emitting chips on the pyrolytic adhesive layer comprises:
arranging a pyrolytic adhesive layer on the front surface of the temporary substrate to form an integrated pyrolytic adhesive layer;
arranging the plurality of micro light-emitting chips on the integrated pyrolytic adhesive layer, and embedding the electrodes of the micro light-emitting chip into the integrated pyrolytic adhesive layer; and
segmenting, by taking a pyrolytic adhesive area corresponding to a single light-emitting chip as a unit, the integrated pyrolytic adhesive layer to obtain the plurality of mutually separated pyrolytic adhesive units which are in one-to-one correspondence with the micro light-emitting chips.

11. The manufacturing method of claim 9, wherein arranging pyrolytic adhesive on a front surface of the temporary substrate to form a pyrolytic adhesive layer, and arranging a plurality of micro light-emitting chips on the pyrolytic adhesive layer comprises:
arranging a pyrolytic adhesive layer on the front surface of the temporary substrate to form an integrated pyrolytic adhesive layer;
segmenting the integrated pyrolytic adhesive layer to obtain the plurality of mutually separated pyrolytic adhesive units which are in one-to-one correspondence with the micro light-emitting chips; and
arranging the plurality of micro light-emitting chips on the plurality of pyrolytic adhesive units respectively.

12. The manufacturing method of claim 9, wherein arranging a plurality of micro light-emitting chips on the pyrolytic adhesive layer comprises:
attaching a surface, on which the electrodes are arranged, of an epitaxial layer of the micro light-emitting chip to the corresponding pyrolytic adhesive unit, or embedding the surface, on which the electrodes are arranged, of the epitaxial layer of the micro light-emitting chip into the pyrolytic adhesive unit.

13. The manufacturing method of claim 10, wherein segmenting the integrated pyrolytic adhesive layer comprises:
segmenting the integrated pyrolytic adhesive layer through an etching process.

14. The manufacturing method of claim 11, wherein segmenting the integrated pyrolytic adhesive layer comprises:
segmenting the integrated pyrolytic adhesive layer through an etching process.

15. A manufacturing method of the display panel of claim 7, comprising:
manufacturing a display backboard and the temporary chip assembly of claim 1, wherein a driving circuit is arranged on a front surface of the display backboard, the driving circuit comprises a plurality of chip bonding areas corresponding to the plurality of micro light-emitting chips, and each chip bonding area is provided with bonding pads corresponding to the electrodes of the micro light-emitting chip; and
transferring each micro light-emitting chip from the temporary substrate to the corresponding chip bonding area to complete bonding, after the bonding is completed, and welding the electrodes of the micro light-emitting chip to the corresponding bonding pads in the chip bonding area, wherein pyrolytic adhesive between the electrodes of the micro light-emitting chip becomes liquid after being heated, and flows to the bonding pads along the electrodes, so as to cover the welding points between the electrodes and the bonding pads.

16. The manufacturing method of claim 15, wherein a de-bonding temperature value of the pyrolytic adhesive is equal to a melting point value of the bonding pads; transferring each micro light-emitting chip from the temporary substrate to the corresponding chip bonding area to complete bonding comprises:
heating the bonding pads so that the bonding pads are melted and welded to the electrodes, and heating the pyrolytic adhesive between the electrodes of the micro light-emitting chip so that the pyrolytic adhesive becomes liquid, in the process of welding the electrodes to the bonding pads, the liquid pyrolytic adhesive flowing to the bonding pads along the electrodes, so as to cover the welding points between the electrodes and the bonding pads.

17. The manufacturing method of claim 15, wherein a de-bonding temperature value of the pyrolytic adhesive is greater than a melting point value of the bonding pads; transferring each micro light-emitting chip from the temporary substrate to the corresponding chip bonding area to complete bonding comprises:
after the electrodes of the micro light-emitting chip are welded to the corresponding bonding pads in the chip bonding area, heating the pyrolytic adhesive between the electrodes of the micro light-emitting chip so that the pyrolytic adhesive becomes liquid and flows to the bonding pads along the electrodes, so as to cover the welding points between the electrodes and the bonding pads.

18. The manufacturing method of claim 17, wherein after the electrodes of the micro light-emitting chip are welded to the corresponding bonding pads in the chip bonding area, heating the pyrolytic adhesive between the electrodes of the micro light-emitting chip so that the pyrolytic adhesive becomes liquid comprises:
starting timing after the electrodes of the micro light-emitting chip are welded to the corresponding bonding pads in the chip bonding area, and after a timing value reaches a preset time threshold, heating the pyrolytic adhesive between the electrodes of the micro light-emitting chip so that the pyrolytic adhesive becomes liquid, wherein the preset time threshold is greater than or equal to 10 seconds and less than or equal to 30 seconds.

19. The manufacturing method of claim 16, wherein transferring each micro light-emitting chip from the temporary substrate to the corresponding chip bonding area to complete bonding comprises:
picking up the micro light-emitting chip up from the temporary substrate through a transfer head, and transferring the micro light-emitting chip to the corresponding chip bonding area;
heating the pyrolytic adhesive between the electrodes of the micro light-emitting chip so that the pyrolytic adhesive becomes liquid comprises:
heating the pyrolytic adhesive between the electrodes of the micro light-emitting chip through the transfer head, so as to make a temperature value of the pyrolytic adhesive greater than or equal to the de-bonding temperature value.

20. The manufacturing method of claim 17, wherein transferring each micro light-emitting chip from the temporary substrate to the corresponding chip bonding area to complete bonding comprises:
picking up the micro light-emitting chip up from the temporary substrate through a transfer head, and transferring the micro light-emitting chip to the corresponding chip bonding area;
heating the pyrolytic adhesive between the electrodes of the micro light-emitting chip so that the pyrolytic adhesive becomes liquid comprises:
heating the pyrolytic adhesive between the electrodes of the micro light-emitting chip through the transfer head, so as to make a temperature value of the pyrolytic adhesive greater than or equal to the de-bonding temperature value.
